(19) United States
(12) Patent Application Publication
(10) Pub. No.: US 2007/0230715 A1
(43) Pub. Date: Oct. 4, 2007

(54) AUDIO LIMITING DEVICE FOR HEADPHONES

(75) Inventors: Christine Ingemi, Amherst, NH (US); William B. Abbott, Hudson, NH (US); Scott J. Asmus, Amherst, NH (US)

Correspondence Address: MAINE & ASMUS, 100 MAIN STREET, P O BOX 3445, NASHUA, NH, 03061-3445, US

(73) Assignee: INGEMI CORP., Amherst, NH (US)

(21) Appl. No.: 11/692,222

(22) Filed: Mar. 28, 2007

Related U.S. Application Data
(60) Provisional application No. 60/786,517, filed on Mar. 28, 2006.

(51) Int. Cl. H04R 1/10; H03G 11/00

(52) U.S. Cl. 381/74; 381/55

(57) ABSTRACT

A system for limiting audio output which in one embodiment includes an audio source, headphones coupled to the audio source, and a limiting circuit coupled to the headphones thereby reducing the power output at the headphones to a safe hearing level. The limiting circuit in one embodiment is integrated into the headphones and can not be disabled.

### RELATED APPLICATIONS

This application claims the benefit of U.S. Provisional Applications No. 60/786,517, filed Mar. 28, 2006 which is herein incorporated in its entirety by reference.

### FIELD OF THE INVENTION

The invention relates to audio applications, and more particularly, to an audio limiting device for headphones.

### BACKGROUND OF THE INVENTION

There has been considerable attention in the media related to the unsafe levels of music provided by small personal audio devices. These high power levels exceed the levels established by the National Institute for Occupational Safety and Health (NIOSH) and Occupational Safety and Health Organization (OSHA).

The problem is even more disconcerting because many of those that are being exposed to these dangerous levels of music are teenagers and those in the pre-teen years that lack the life experience to make informed health decisions.

The popularity of personal portable music devices such as the Apple iPod and other MP3 players has been phenomenal. Millions of these devices have been sold and allow the user to listen to digital music recordings using some form of headphones such as earbuds, earphones stereophones and headsets.

These audio devices serve a valuable and important function of providing the user with convenient quality audio recordings for enjoyment. Audio recording can be downloaded from the Internet or otherwise extracted in a digital format and stored on the portable audio device. The sound quality is very good and the portability allows for audio enjoyment in any location.

They are also becoming increasingly popular for information and educational content. Users can download various audio recordings of books and instructions, including class lectures. Schools are providing “podcasts” which are audio/video programs that can be downloaded from the Internet and heard by students via headphones.

While these audio devices can be useful, some users are using the devices and increasing the volume to unacceptable safe hearing levels. A 2006 poll conducted for The American Speech-Language-Hearing Association (ASHA) found that 53 percent of high school students said they were concerned about hearing loss. And, the same poll indicated the 59 percent indicated they still played music at high volumes on the MP3 players. In the Zogby International poll, more than half of high school students (51 percent) said they had experienced at least one of the symptoms of hearing loss. Furthermore, the National Institutes of Health estimates that 22 million American adults ages 20 to 69 have suffered hearing damage from loud noises.

Those listening to the audio devices are not only listening to high volume levels, they are also listening to these high volume levels for extended periods of time, sometimes hours at a time. The combination of listening louder and longer contributes to the hearing damage potential.

And, this is regardless of the warnings in the product literature and in the media. There have been numerous announcements from health organizations to replace the popular earbud-style earphones that are sold with many MP3 players with noise-canceling headphones or more traditional headphones that cover the ear thereby blocking external background noise, allowing users to play their music more softly. However approximately 23 percent of students said they have bought aftermarket headphones.

A majority of parents (59 percent) said they were concerned about their children suffering hearing loss from listening to electronic devices with earphones, but less than half said they limit the amount of time their children can use those devices. An overwhelming majority of parents (80%) have indicated that they made their children lower the volume, and more than half of parents indicated they have talked to their children about the problem. Only 10 percent of students said that warnings from parents or friends would be an effective way to teach them about the dangers of hearing loss.

In response to the public outcry, there has even been some movement in Congress to conduct safety studies on the MP3 audio players to determine if legislation is necessary to thwart a health hazard.

According to James Battey, director of the NIH's National Institute on Deafness and Other Communication Disorders, “[t]he amount of research on the effects on NIHL (noise-induced hearing loss) by loud music from portable devices decreased slightly in the late 1990s with a resurgence in the past few years following the introduction of the portable MP3 player. All of these devices have maximum sound output levels that range from 115 to 130 decibels (dB), which is comparable to the sound level of a jet engine.”

For younger children, the hearing damage from this loud music can have long term and possibly permanent effects. The effects can reduce the person's ability to hear low level audio and can also reduce the frequency range. Hearing problems at an early age affects learning and speech which can result in educational and social problems that might otherwise be non-existent.

There are some existing schemes designed to implement some form of audio limiting. Many of these are high component count implementations with elaborate designs that would have a higher cost and a larger form factor for any implementation.

There are known designs that can limit the power at the audio source however it is clear that certain members of the public do not wish to limit the power output capability. There is also the volume control that would allow the user to lower the volume if desired. Based on recent studies, the users may lack the maturity and sound judgment to lower the volume or otherwise restrict potentially harmful volumes.

Some devices provide a sound damping that are fixed attenuators to decrease the power output by a certain level. While these devices lower the power level regardless of the applied power, they tend to waste power and therefore battery life for portable devices.

Therefore, it is apparent that the various MP3 and audio devices are operated at power levels that are above the safe thresholds. The users may or may not recognize that there is a potential for hearing damage, but the majority of these users do not care about the effects or are generally apathetic. Children in particular lack good judgment about the side effects and are more likely to listen to music at unsafe levels. While the use has some volume control abilities, the vast majority of users do not lower the volume, and some users are even adding amplifier stages. Furthermore, instead of using headphones that block external noise thereby allowing a lower volume, users employ earbuds which generate even more harmful levels directly into the ear.

The noise cancellation headphones may provide some help in reducing the audio output since there is no external noise that needs to be surmounted, there is still no limit to the audio output that the user can select. Furthermore, while the noise cancellation devices remove the noise generated in the surrounding environment, they can pose a safety threat. There have been tragic instances of children being hit by trains and run over by vehicles that were attributed to the use of noise canceling products wherein these individuals were unable to hear external threatening noises. Thus while the noise canceling may be useful in some instances, there is still a strong interest in having a safer headphone.

Schools, both public and private, require a safe alternative for students to employ headphones. The same applies to public libraries, museums and government offices that provide access to headphones and audio and audio/video resources. The business community also recognizes that employees may be listening to unhealthy music levels. For example, the software developers and web designers typically use computers and headphones as part of their job description. The employers wish to ensure safe working environments, especially in a litigious society, and also perceive a need for a safer mechanism to protect their work force and ensure compliance with governmental regulations and recommendations.

What is needed, therefore, is a device and system that will lower the audio output from a headphone to a safer level. The device should be inexpensive and easily implemented. There are even certain applications where the device should have a fixed audio limiting device that will not be easily circumvented.

### SUMMARY OF THE INVENTION

One embodiment of the present invention provides an improved audio limiting device to solve the aforementioned problems.

One embodiment is a system for establishing a safe audio output from an audio source, comprising a limiting circuit electrically coupled to the audio source wherein the limiting circuit reduces the audio output signal to the safe audio output. A headphone is electrically coupled to the safe audio output so that the user can only hear the safe audio output. According to a further feature, the limiting circuit is integrally coupled and can not be disabled or circumvented. The system can be used for multiple channels.

In another embodiment, the headphone is selected from at least one of the group of devices consisting of: earbuds, earphones, stereophones and headsets. The audio source can be selected from at least one of the group of devices consisting of: iPod, laptop, cellphone, video game, television, stereo, personal digital assistant, personal computer, and tablet.

An additional aspect is that the audio source is coupled to the headphone by lead wires, and wherein the limiting circuit is integrated into the wires.

The safe audio output according to one example is 80 dB. Lower levels such as 75 dB, 70 dB, 65 dB and 60 dB are other examples. A still further example is a selectable safe audio selection such as selecting 75 dB or 80 dB.

In one implementation there can be an opposing pair of Schottky barrier diodes coupled parallel to the headphone. The limiting circuit in one embodiment includes at least one resistor coupled in series.

In one example, the headphone is wireless, wherein the limiting circuit can be integrated into the wireless headphone.

Another embodiment of the invention is an audio limiting apparatus providing a safer listening experience, comprising a headphone operatively coupled to an audio source, with a limiting circuit coupled to the headphone thereby reducing the power output. The limiting circuit may further comprise a pair of opposing diodes coupled in parallel and at least one series coupled resistor for reducing the output power to a fixed amount. The first resistor can be coupled between the audio source and the diodes. This first resistor in one example has an impedance approximating the headphone impedance.

One feature includes having the diodes selected from the group consisting of Schottky barrier diodes and germanium diodes.

The fixed amount in one example is a difference between a safe output power level and a headphone output power level.

An additional embodiment is a system for safe hearing, comprising a headphone operatively coupled to an audio source and proximate at least one ear of a user. There is a limiting device that reduces an audio power level to a safe level, wherein the limiting device is securably affixed to avoid circumvention.

According to one example, the limiting device is a limiting connector. The limiting connector can be secured to a jack of the headphone and then simply plug into the audio device.

In one example, the limiting device further comprises a pair of opposing diodes coupled parallel to the headphone and at least two series coupled resistors.

Another embodiment of the present invention provides an audio limiting device located in-line with the earbuds and headsets to lower the audio output. The audio limiting device in one embodiment is fixed such that there is no ability to disable or increase the output volume.

A still further embodiment is an audio limiting system that provides for an external input such as a microphone, wherein the microphone provides the audio source that is subject to the limiting. According to one embodiment, such a system could be used at concerts to allow for undampened concert audio but ensuring that such input does not exceed a safe threshold. A variation involves industrial usage such that the operator can hear a safe audio input level of the external environment which is a safer version of the environment dampening earmuffs.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1 is a perspective illustration showing an audio device configured in accordance with one embodiment of the present invention.

FIG. 2a is a schematic diagram illustrating an audio limiting design configured in accordance with one embodiment of the present invention.

FIG. 2b is a block diagram illustrating an audio limiting design with filtering configured in accordance with one embodiment of the present invention.

FIG. 2c is a block diagram illustrating an audio limiting design with filtering configured in accordance with another embodiment of the present invention.

FIG. 3 is a schematic diagram illustrating the audio limiting design on both channels and configured in accordance with one embodiment of the present invention.

FIG. 4a is a diagram a wireless headphone embodiment configured in accordance with one embodiment of the present invention.

FIG. 4b is a perspective view of the limiting circuit integrated into a jack and configured in accordance with one embodiment of the present invention.

FIG. 5a illustrates another limiter circuit design with a variable resistor according to a further embodiment of the invention.

FIG. 5b illustrates another limiter circuit design according to another embodiment of the invention.

FIG. 6a shows the limiter device with a noise cancellation headphone.

FIG. 6b shows the limiter device with a wireless noise cancellation headphone.

FIG. 7a depicts a partial view of the housing for the limiter including a break-away safety feature according to one embodiment.

FIG. 7b illustrates another embodiment for a break-away safety feature for the wired version of the headphones.

FIG. 7c is a further embodiment of the safety feature with the break-away.

FIG. 8 shows another embodiment for the invention that allows for external environment input.

### DETAILED DESCRIPTION

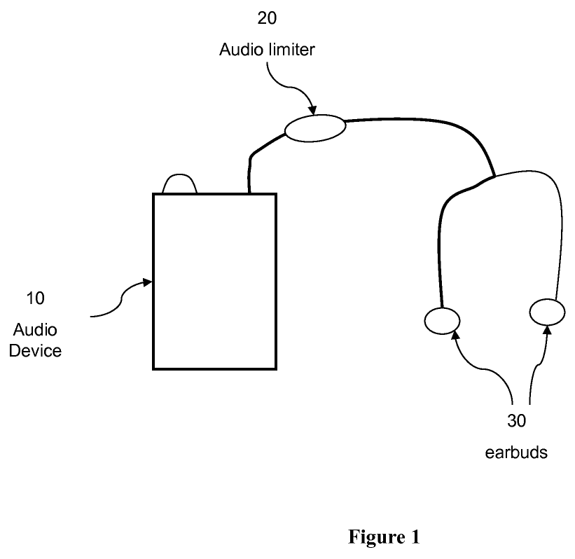

Referring to the embodiment of FIG. 1, the audio device 10 is coupled by wire to a headphone 30 with the audio limiting device 20 integrated into the wire. The audio device 10 is intended to cover any and all electronic devices that have the ability to produce audio outputs, hereinafter termed personal audio devices and is coupled to some form of headphone such as earbuds and headsets. The audio device 10 includes any of the devices such as Apple iPod®, MP3 players, cell phones as well as other audio devices such as portable radios, Sony Walkman®, televisions, and “boom boxes.” Such audio devices 10 also include computing devices such as computers, laptops, tablets, and personal digital assistants (PDAs), all of which typically have an audio output capability. There are various entertainment systems such as those incorporating virtual reality headgear that can also benefit from the present invention and are included herein. Furthermore, headphones integrated with radio and satellite radio reception are to be considered audio devices as they provide an audio source. Also included in this group of audio devices are those devices that are coupled to Internet radio.

The headphone 30 provides the mechanism to transmit the audio information from the audio device 10 to the user and typically includes some form of speaker. The headphone 10 includes wired and wireless headphones such as earbuds, headsets, earphones, stereophones, and related devices, and specifically includes Bluetooth and related wireless standards. This also includes the various earpieces used with respect to cell phones.

The audio limiting device 20 includes an electronic circuit that drops the output power from the audio device 10 to a lower level prior to being processed by the headphones 30.

In this embodiment, the components (not shown) of the limiting device 20 are manufactured on a small printed circuit board (PCB) and packaged in a hardened plastic shell with the headphone leads 25 electrically coupled to the PCB. The PCB in one implementation has test points.

The leads 25 can also be secured within the shell by the pressure fit from the closed shell. Adhesives are also within the scope of the invention to retain the leads and/or seal the shell. Certain other embodiment can include watertight or waterproof shell designs that may protect the circuit from environmental conditions.

While the audio limiting device 20 is depicted in the headphone wires, it is adaptable to be fitted into wireless headphones. A typical wireless headphone employs a receiver section that processes the received audio data and generates the audio signal that is then output from the speakers. The audio limiting design of the present invention can be integrated into the electronics of the headphone between the receiver portion and the speaker.

By way of illustration of wireless technology, Bluetooth is a low-power-consumption and short-range wireless technology for personal area networks (PANs) that connects various electronic devices, such as laptops, mobile phones, digital cameras, audio equipments, and printers, without cables. The wireless headphones allow for portability to allow motion and movement within the region of the transmitting device. The Bluetooth network uses an unlicensed radio frequency at 2.45 GHz. A Bluetooth device typically has a range of ten meters (32 feet), and a data rate close to 300 kbps. Since the 2.45 GHz radio wave can penetrate walls, you can connect Bluetooth devices across rooms. However, there are other wireless technologies and headphones that allow wireless communications with the wireless headphone units and the present invention is not limited to Bluetooth technology.

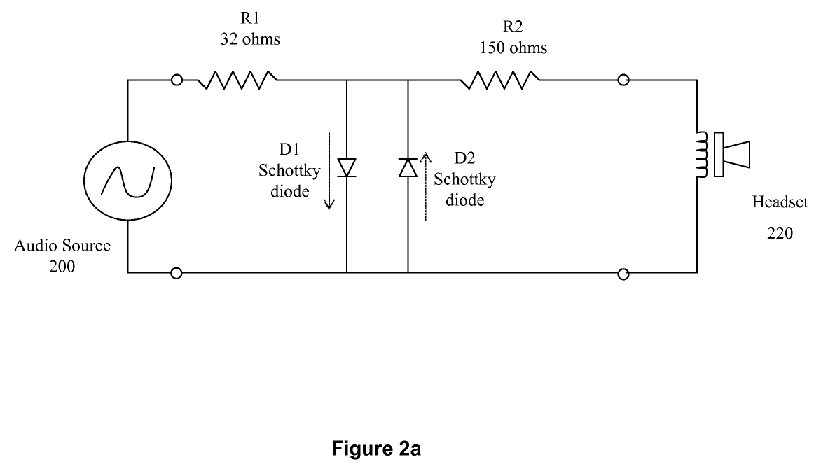

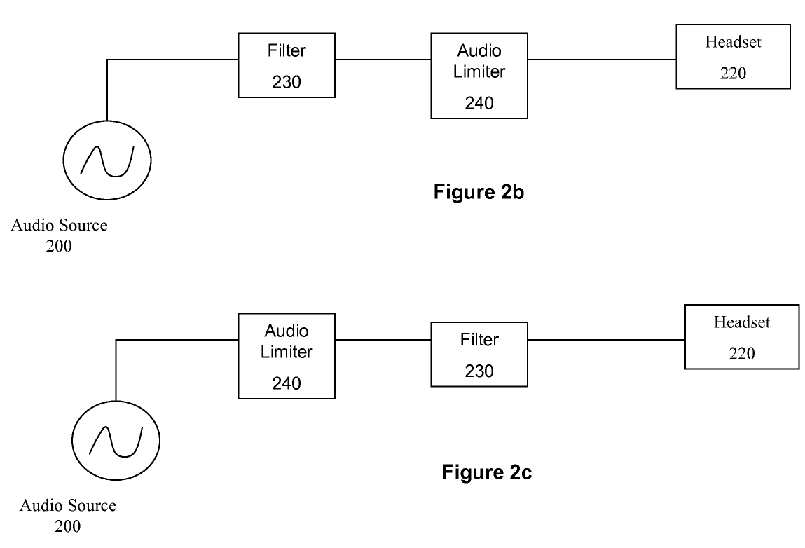

Referring to FIG. 2a, one embodiment of the audio limiting device is illustrated for one channel. In most stereo applications, two channels would require two circuits. The audio source 200 represents the incoming audio signal whether it is being output from an iPod and traveling through the wires of a wired headphone 220 or whether it is coming from the receiver portion of a wireless headphone 220. This further includes any boosting or amplifying stage that may be employed as well as filtering.

In this particular design, a pair of Schottky barrier diodes D1, D2 is coupled in parallel with the audio source 200. The diodes operate like one-way switches and allow current to flow in the direction of the arrows. Diodes D1 and D2 are non-linear devices which limit the incoming signal to approximately 0.25 Volts or 250 millivolts. This limits the maximum power which can be applied to the earbuds. If higher volumes are attempted, no further volume increase will result. In certain embodiments the sound may become distorted if the diodes are saturated, and this may prompt the user to reduce the volume.

In limiting, the attenuating resistor, R2 further attenuates the limited signal by about 15 Decibels (dB). Before limiting occurs, R1 and R2 attenuate the incoming signal by about 16.5 dB. The result is that power to the earbud never exceeds an audio power of greater than about 80 dB.

In order to reduce the output power from the audio source according to this embodiment, a resistance is employed using two resistors R1, R2. The resistors R1, R2 are in series with the audio signal and in this embodiment comprise two separate resistors R1, R2. Resistor R1 is approximately 32 ohms, which is roughly the resistance of the headphone 220 for this embodiment. It is not necessary that the series resistance match the headphone resistance. Resistor R1 also acts as a safety mechanism such that in the event that one of the diodes fails there will be an impedance such that there will be no damage to the audio source 200. The other resistor R2 in combination with resistor R1 cumulatively provides a certain resistance such that the audio power is dropped. While the resistive approach to limiting output power would appear to be inefficient, with output power in the milliwatt range, the effect on power consumption and battery life is negligible.

The attenuation for one embodiment is calculated based on the properties of the expected parameters of the headphone. For example, assuming the headphone is an earbud with an output level of 95 dB/1 mW; a maximum rating of 5 mW and an impedance of 32 ohms, the circuit parameters are calculated as follows:

D1 and D2 limit peak output voltage to 0.25 V Peak to Peak This corresponds to an rms (root mean square) voltage of:

0.707×0.25 Vp=0.1768 Vrms

Power=E²/R=(0.1768)²/32=0.98 mW (milliwatt)

This is close to the output level of the headphone which is about 1.0 mW, wherein this corresponds to a sound power level of 95 dB per the specifications of this particular earbud. This represents the maximum output by using the diodes D1, D2 without any further attenuation. Thus, for this embodiment, the resistive attenuation is required to lower the noise power.

Assuming a 95 dB maximum input, and assuming a desired output level of 80 dB, thus the goal is to reduce (attenuate) the audio power as follows:

95 db−80 dB=15 dB

Attenuation in decibel (dB)=20 log₁₀(voltage reduction ratio) (20 log₁₀) (X)=−15 dB

X=10^{(-15/20)}=0.1778 which represent the voltage reduction ratio

Using the determined ratio of 0.1778 for a −15 dB attenuation:

0.1778=32/(R2+32)

R2=148 ohms

Using a standard value of 150 ohms as an approximation of 148 ohms, the limiting effects are as follows:

### In Limiting:

Attenuation=20 log(32/(150+32))=15.1 dB

### Before Limiting:

Attenuation=20 log(32/(32+150+32))=16.5 dB

FIG. 2b and FIG. 2c shows embodiments that incorporate filtering of the signal from the audio source 200 by some type of filter 230 before and/or after the limiter circuit 240. For example, a band pass filter can be incorporated to only allow the frequency range of interest while minimizing or eliminating any frequencies outside the selected range. The typical hearing range is 20 Hz to 20 kHz and is the band pass filter range according to one embodiment. Other filter stages are further embodiments such as low pass filter to eliminate high frequency noises and high pass filter to eliminate low frequency noise. Various combinations of filter stages are additional embodiments including having filtering both before and after the limiter stage 240.

Recent human auditory studies have postulated that the perception range for high frequency sound is much greater than 20 kHz for humans and that certain signals can be interpreted above the well-established 20 kHz bounds. According to certain embodiments, the frequency range is undisturbed, and audio sources with upper frequency bounds such as 40 kHz and 60 kHz can be used with embodiments of the invention.

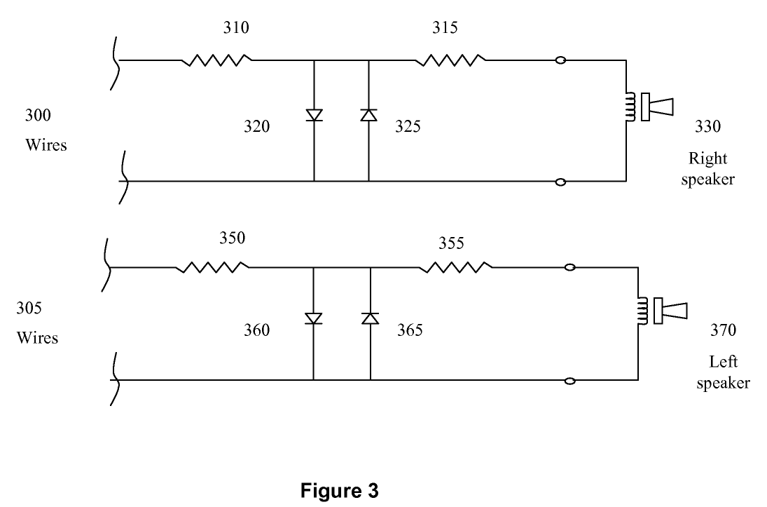

FIG. 3 shows another embodiment, which is the audio limiting device on each channel of a stereo system. The wires from a first channel 300 include a first series resistor 310 followed by a pair of opposingly coupled diodes 320, 325 coupled in parallel, and a second series resistor 315. The speaker 330 of the headphones is coupled to the output after the second resistor 315.

A similar circuit is evident on the other channel. The wires of the second channel 305 are coupled to a series connected first resistor 350. The pair of opposingly coupled Schottky diodes 360, 365 are coupled in parallel following the first series resistor 350. A further series connected resistor 355 is coupled after the diodes 360, 365. The output from the second resistor 355 is coupled to the headphone speaker 370. In this manner the audio output to each channel is limited.

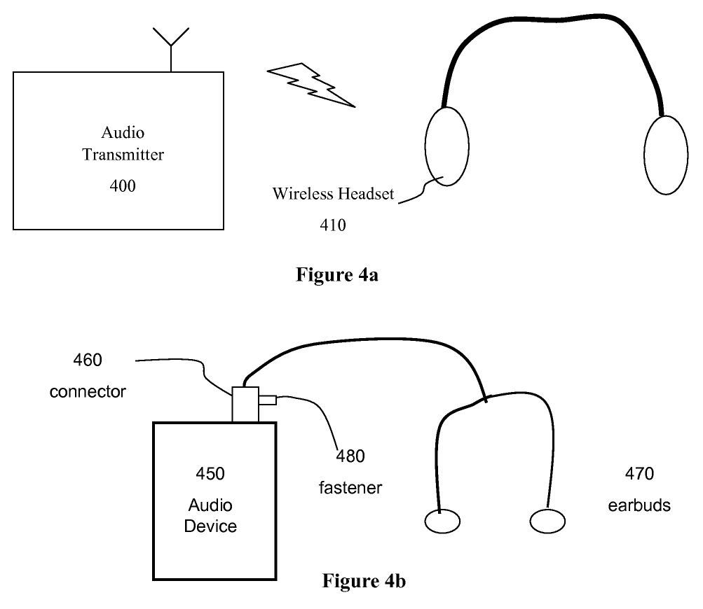

Referring to FIG. 4a, a further embodiment of is depicted for a wireless headphone 410. In this embodiment, there is an audio device having some form of wireless transmitter unit 400. The audio device 400 includes many devices such as a personal computer, laptop, tablet, cell phone, iPod, and personal digital assistant which include some means for wireless transmission. The wireless headphone 410 can be any form of headset including earbuds and headphones. Within the headphone 410 is a receiver section and a processing section (not shown) that is well-known in the art. The audio limiting designs detailed herein are integrated into the processing circuitry of the headphone 410 after the receiver processing section and before the speaker of the headphone 410.

FIG. 4b illustrates the audio limiting circuit integrated into a connector assembly 460 such as a jack that can be plugged into the audio source 450. The headphone 470 can then be plugged into the connector 460 thereby having an audio limiting device for the existing headphones 470.

According to one embodiment, the mating connection between the existing jack of the headphone 470 and the connector 460 are fixedly coupled such as by mechanical means or adhesives. The connector 460 can incorporate an adhesive compound (not shown) such that once the headphone 470 jack is inserted into the limiting connector 460, it is affixed. The connector 460 can have a mechanical fastener 480, such as a set screw, that can be used to affix the limiting connector 460 to the headset 470 jack. Such fasteners 480 can lie in a recessed portion of the connector 460 when secured and may include various heads that would make it difficult to unscrew such as hex, torqx, or locking heads. Other mechanical retention fasteners can be incorporated with the connector 460 so as to mechanically grip the inserted jack 470 it is held in place. There are a number of push retainers and the usage also includes a connector having fingers, metal or plastic, that are angled inwardly such that they grip the inserted jack 470.

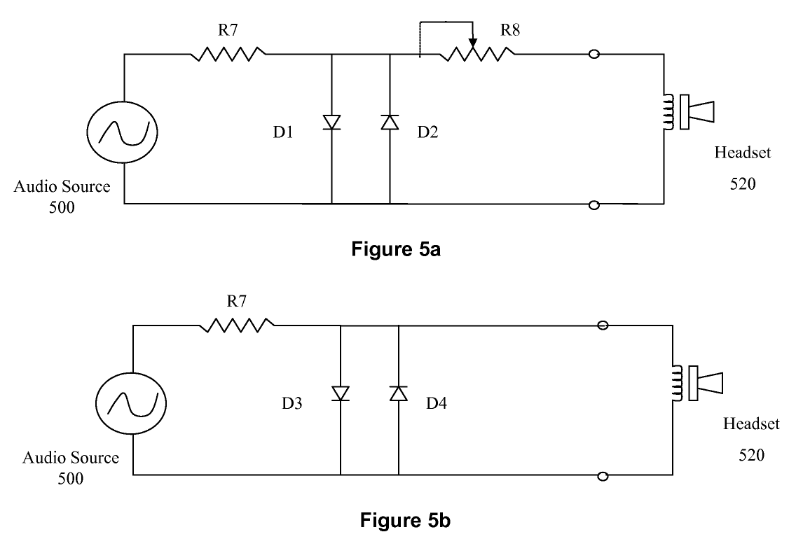

A further embodiment is illustrated in FIG. 5a, wherein resistor R8 is variable and can be used to adjust the resistance and therefore adjusts the limiting effect. The variable resistor R8 can be deployed as a setting within the package either as a variable potentiometer so the user, such as a parent, can select the appropriate level. Alternatively, the settings can be pre-calculated to allow the output parameters to be selectable, such as a ‘High Attenuation’ and ‘Low Attenuation’ and selectable by a switch or switching mechanism. This setting can be used, for example, such that the high attenuation might limit the output to 75 db while the low attenuation might be 80 dB. In another embodiment, instead of a potentiometer, a switch with individual resistors of different values can replace R8 such that the switch path couples to a single resistor value and can establish, for example, a high attenuation path, a medium attenuation path, and allow attenuation path. Regardless of whether the variable resistor R8 is adjusted by a potentiometer or a switch, the setting can be fixed by various means such as an adhesive or a set screw. There can also be a control arm that is removed after making the setting such as by breaking a weak point that is flush or recessed from the surface or wherein the control arm is removable from the resistor setting mechanism.

In order to preserve the non-circumventible nature, the switch setting could be via an access hole or push pin style interface.

Referring to FIG. 5b, the diodes D3 and D4 are selected such that they limit the output voltage to a certain level and thereby provide a maximum output threshold lower than the 95 dB level. The resistor R7 provides further attenuation of the audio power and also provides some impedance in the event that the diodes D3, D4 malfunction so that the audio source 500 would see some circuit impedance.

In this particular embodiment, if the diodes D3 and D4 limit peak output voltage to a value approximately equal to 0.20 V Peak to Peak This corresponds to an rms (root mean square) voltage of:

0.707×0.20 Vp=0.1414 Vrms

Power=E²/R=(0.1414)²/32=0.625 mW (milliwatt)

Attenuation=10 log₁₀(0.625 mW)=−2.04 dB

95 dB−2.0 dB=93 db; 93 dB−80 dB=13 dB

(note: 10 log₁₀(0.625 mW/1.0 mW)

Attenuation in decibel (dB)=20 log(voltage reduction ratio) 20 log₁₀x=13 dB

X=10^{(-13/20)}=0.2239 which represent the voltage reduction ratio

Using the determined ratio of 0.2239 for a −13 dB attenuation:

0.2239=32/(R2+32)

R7=111 ohms

Thus, a lower diode threshold equates to a lower resistance and therefore less power consumption. As described herein, the use of 80 dB as the limit level is used as a reasonable power level however any limit level can be achieved as noted herein by altering circuit parameters. For younger children a lower limit such as 75 dB, may be established and be integrated into the headphone so that it can not be disabled by the user. Further information about standards for noise is published by the Occupational Safe and Healthy Organization (OSHA) and such details are available at http://www.osha.gov/SLTC/teenworkers/hazards_noise.html.

There are few diodes that may have the desired characteristics. Germanium diodes have low threshold voltages in the above-referenced range and the present invention according to one embodiment employs Germanium diodes to limit the output power as described herein. Other types of diodes with similar characteristics are within the scope of the invention.

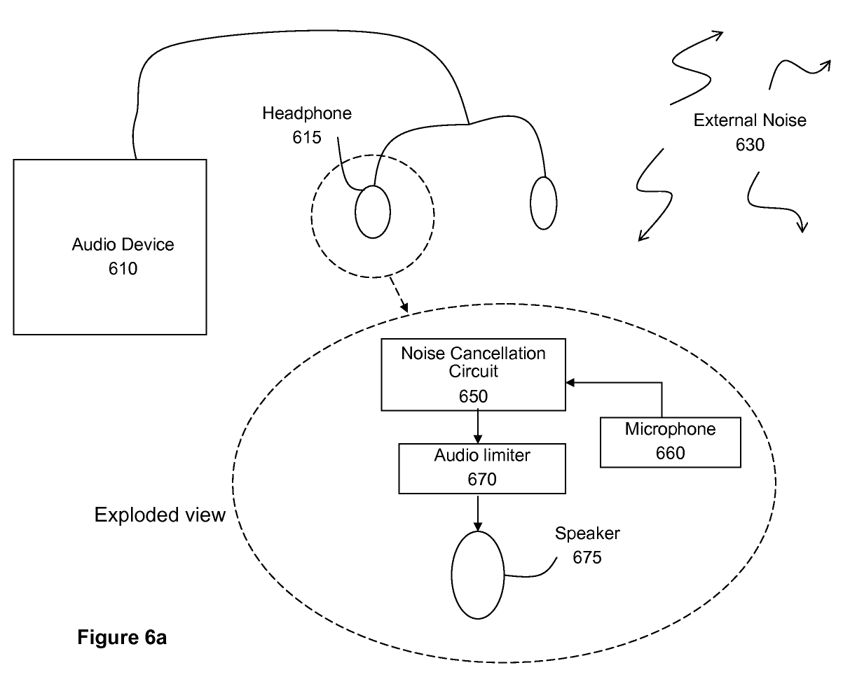

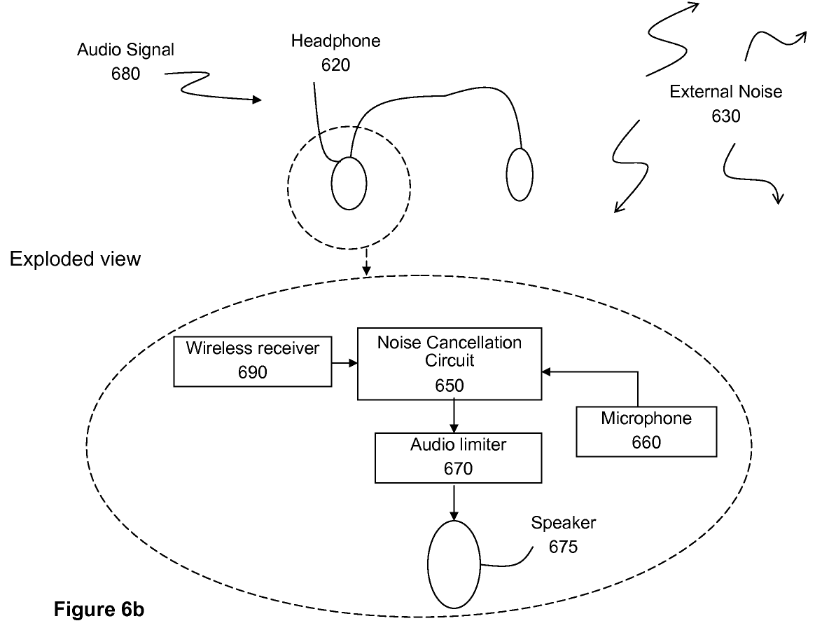

Another embodiment relates to the filtering and noise cancellation headphones such as shown in FIG. 6a and 6b. There are many different types of noise suppression and noise cancellation designs that can be incorporated with headphones. Some such designs are used to filter the audio signal by removing extraneous or undesirable components such as harmonics. There are also active noise cancellation designs that reduce the external noise from the surrounding environment. By reducing this external noise, the user can more clearly appreciate the signals of interest and presumably keep the volume at a lower level.

Referring to FIG. 6a, the audio device 610 transmits the audio signal to the headphone 615. Within the headphone 615 is a noise cancellation circuit 650 which uses some form of microphone 660 to detect external noise 630. The noise cancellation circuit 650 cancels or reduces the external noise 630. The audio output from the noise cancellation circuit 650 is then limited in power by the audio limiter 670 to reduce the level to a safe level prior to the transmission to the speaker 675.

A wireless noise cancellation headphone 620 is shown in FIG. 6b. An audio signal such as from an audio device or radio transmission 680 is processed by a receiver section 690 which may amplify and filter the received signal. The noise cancellation circuit 650 processes the received signal to reduce the effects of the external noise 630 detected by the microphone 660. The output of the noise cancellation circuit is then lowered to a safe audio level by the limiter 670 before being transmitted to the speaker 675.

Certain embodiments of the invention include a ‘break-away’ safety feature to avoid strangulation. Whenever wires are placed in proximity of a person's neck, the risk of accidental strangulation or other injury should be considered. For example, the wires could become entangled or otherwise engaged with some other object, machinery, or the like, injury may result. In order to prevent any such injury, the system may be designed with a break-away feature before a dangerous degree of tension can be produced in the wires.

In one embodiment, the tensile strength of the wires themselves can be selected so as to break upon an unsafe tension. In another embodiment, the system can include a weak portion that breaks or releases at a predetermined tension. Furthermore, the engagement of the wires into the audio limiting package can be designed to release at a predetermined tension. While there are no safety guarantees, this break-away headphone lead attachment is intended to prevent strangulation. The leads can be secured to a plastic post within the shell and then electrically coupled to the PCB, wherein the post would be the weak spot allowing the break-away. Another implementation of the break-away is a mating coupling such as used on key chains.

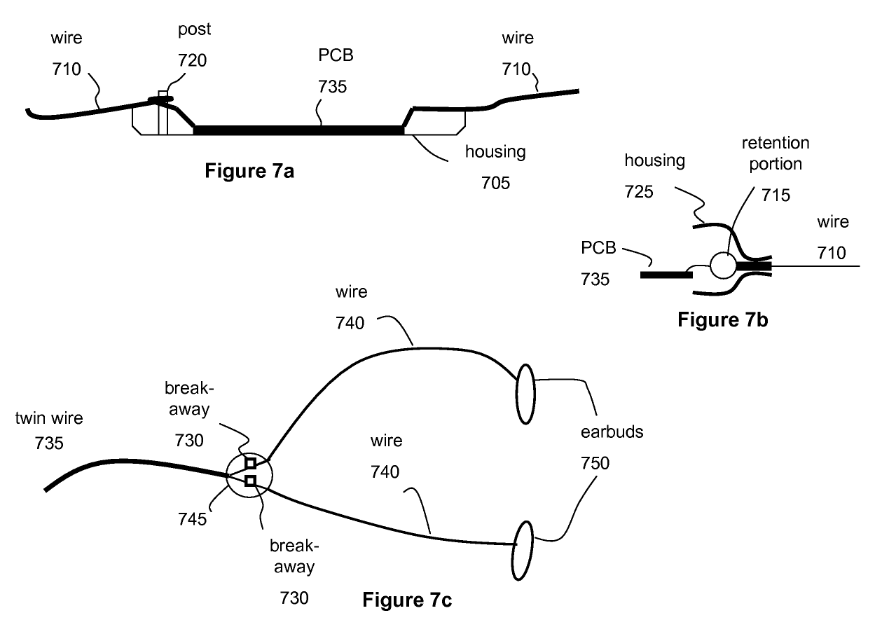

Referring to FIG. 7a, according to one embodiment, the lead wires 710, such as a single wire or a double wire, are retained within the plastic housing or shell 705 but provides for break-away if the headphone wires 710 are pulled too tightly. According to this embodiment, a post 720 is used to provide the required tensile strength and the wire 710 would be coupled to the post 720 such as wrapped or tied around the post 720. The wire 710 would then connect to the printed circuit board (PCB) 735. If the wire 710 were pulled too tightly, the post 720 would snap and the wire connection at the PCB 735 would break. An alternative feature includes a wire connector (not shown) on the end of the wire 710 and a mating connector (not shown) on the PCB board 735 such that the shell 705 can be opened and the wire 710 can be reconnected to the PCB 735. The post 720 can be on one or both sides of the housing 705.

Referring to the embodiment of FIG. 7b, one implementation of the break-away is to use a housing 725 that has a shape that is amenable to a retention portion 715 that is held by the housing 725 until sufficient tension is applied. As shown in this embodiment, the retention portion 715 is coupled to the wire 710 and is larger than the opening in the housing 725. The retention portion 715 can be adhered or affixed to the wire 710 such that when sufficient tension is applied and the retention portion 715 is pulled through the housing 725 the connection of the wire 710 and the PCB 735 would release. Various designs and retention mechanisms are known in the art and can be incorporated.

In FIG. 7c, the twin wire 735 has a location that splits the twin wire 735 into two wires (eg: signal wire and shield) 740 for each earbud. At this junction, a plastic portion 745 is typically integrated to keep the twin wire from separating further down, which also provides a location for a break-away feature. At this portion, the wires can have a weakened segment 730 to allow for breakage which can be wire connectors or other links that have a lower tensile strength than the wires 740.

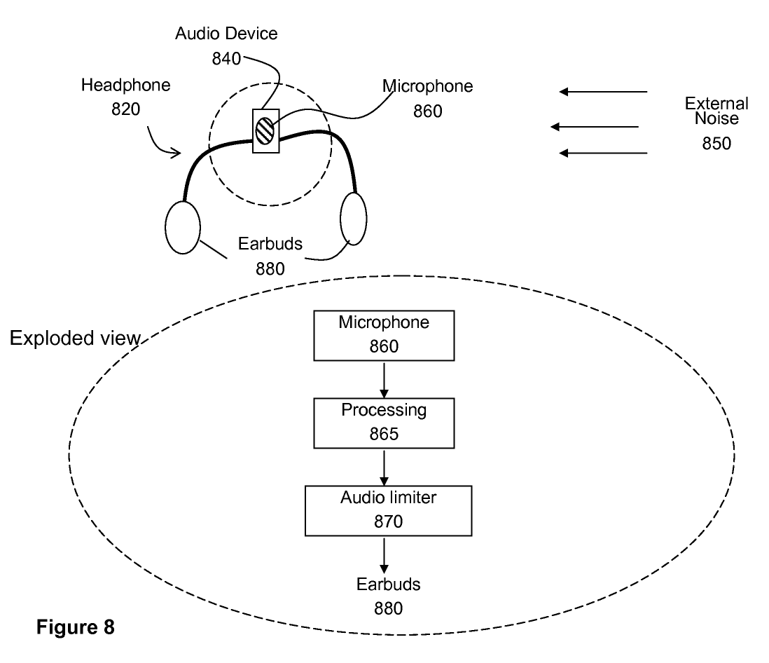

Referring to FIG. 8, a further embodiment is a headphone 820 with an audio device 840, wherein the audio device 840 incorporates a microphone 860 to extract signals and noise from the external environment 850. The microphone 860 converts that sound waves (pressure changes) to voltage changes that is processed 865 into an audio signal which further includes audio limiting of the audio signal to a safe level 870. The safe audio signal is then reformed into sound at the speaker 880 which essentially converts the voltage changes to sound (pressure changes). The processing can include amplification and filtering to render a better quality signal. The audio device 840 can be a separate electronic device that include a microphone, such as a cell phone, or simply part of the headphones 820. Unlike noise cancellation headphones, one embodiment of the present invention eliminates such processing and simply allows the user to listen to the external signals and noise 850 at a safe level while still hearing an undampened environment.

One application for such a system is for concerts in which the concert attendee wishes to listen to the actual concert environment, but at a safer audible level. A microphone 860 can be coupled to headphones 840 and extract the concert noise that is processed and then limited to a safe level prior to reaching the ears. A device 840 with a microphone 860 can be used including a cell phone or other portable listening device, hereinafter called a microphone device in order to be the audio source. The microphone 860 can be omnidirectional or directional in order to limit noise to a specific area. One embodiment provides for the microphone device to be coupled to the headphones itself. The processing 865 can be accomplished with circuitry in the headset itself, within the microphone device, or with a separate audio device. The system can be wired or wireless as would be readily ascertainable to one skilled in the art.

A further implementation relates to limiting the headphone power in relation to video games. There are many computer-related games, such as X-Box, having noisy interactions and the parents tend to prefer that the gamers use headphones. These games can employ televisions, stereo equipment and/or computers, wherein the headphones can incorporate a fixed attenuation to prevent hearing loss. A further implementation refers to a wireless television listening system known as TV Ears that retransmits television audio to headphones. Such headphones can incorporate the safe level audio limiting embodiments detailed herein.

According to one embodiment, the audio limiting is designed for younger adults and children. The housing for the limiter can be used for advertising or otherwise manufactured to be aesthetically pleasing to the younger crowd. Besides the color and display features, the housing can also be manufactured in different shapes and sizes, such as dinosaurs and cars. Thus, one embodiment of the invention encompasses a housing with different colors, different shapes, designs/logos, and textual messages.

Another embodiment allows for after market implementation into an existing headphone. The audio limiter can be sold as a kit with a clamshell plastic housing that retains the PCB wherein the user would cut the headphone lead wire and electrically couple the lead wire to the PCB. The housing would then be closed and securely fastened.

Another embodiment for after market installation includes the limiter connector fastened to the jack from the headphones. Such an implementation would thus couple the limiting connector to existing headphones.

The safe hearing implementations of the present invention are applicable in many applications and environments. For example, in the school systems the use of electronic devices and computers is proliferating and electronic classrooms are in use. For the safety of the students, the schools can require the lowered volume outputs available with the present invention. Likewise, town libraries and government buildings should implement safer headsets. Various forms of policies and regulations can be implemented that would mandate such usage to ensure implementation.

In addition to the headphones, the audio limiter device is also applicable in other situations that may warrant an audio output limitation. For example, most personal computers come with speakers and a volume control that can be turned to a fairly high level that may not only be a potential safety issue, but may be generally obnoxious to others in the vicinity. The present invention can be integrated with the speaker leads either as a new product, an after-market installation, or installed as a jack that will allow the speaker jack to be inserted. The various affixing techniques can be used for these other embodiments.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto.

What is claimed is:

1. A system for establishing a safe audio output from an audio source, comprising:
a limiting circuit electrically coupled to said audio source wherein said limiting circuit limits an audio output signal to said safe audio output; and
a headphone electrically coupled to said safe audio output, wherein said limiting circuit is integrally coupled with said headphone and is non-detachable.

2. The system of claim 1 further comprising a wired connection between said audio source and said headphone, wherein said wired connection includes a break-away.

3. The system of claim 1 wherein said headphone is selected from at least one of the group of devices consisting of: earbuds, earphones, stereophones and headsets.

4. The system of claim 1 wherein said audio source is selected from at least one of the group of devices consisting of: iPod, laptop, cellphone, video game, television, stereo, personal digital assistant, personal computer, tablet, radio, personal audio device.

5. The system of claim 1 wherein audio source is coupled to said headphone by lead wires, and wherein said limiting circuit is in a housing integrated into said lead wires.

6. The system of claim 1 wherein said safe audio output is less than about 80 B.

7. The system of claim 1 wherein said limiting circuit includes at least one resistor coupled in series.

9. The system of claim 1 wherein said limiting circuit includes an opposing pair of Schottky barrier diodes coupled parallel to said headphone.

10. The system of claim 1 wherein said safe audio output is an adjustable level.

11. The system of claim 1 wherein said headphone is wireless and said limiting circuit is integrated into said wireless headphone and can not be disabled.

12. The system of claim 1 further comprising a microphone coupled to said audio source and providing the audio output signal.

13. An audio limiting apparatus providing a safer listening experience, comprising:
a headphone operatively coupled to an audio source, said audio source transmitting an audio power output;
a limiting circuit coupled to said headphone and said audio source and reducing the audio power output, wherein said limiting circuit comprises:
a pair of opposing diodes coupled parallel to said headphone; and
at least one series coupled resistor for reducing the audio output power.

14. The apparatus of claim 13 wherein a first resistor is coupled between said audio source and said diodes.

15. The apparatus of claim 14 wherein said first resistor has an impedance approximating an impedance of said headphone.

16. The apparatus of claim 13 wherein said diodes are selected from the group consisting of Schottky barrier diodes and germanium diodes.

17. The apparatus of claim 13 wherein said series coupled resistor reduces said audio output power by a fixed amount, said fixed amount is a difference between a safe output power level and a headphone output power level.

18. A system for safe hearing, comprising:
a headphone operatively coupled to an audio source and proximate at least one ear of a user;
a limiting device that reduces an audio power level of said audio source to a safe level, wherein said limiting device includes at least one resistor for attenuating said audio power level and a pair of diodes that establish a maximum level for said audio power level, and wherein said limiting device is securably affixed to avoid circumvention.

19. The system of claim 18 wherein said limiting device is a limiting connector securably attached to a headphone jack.

20. The system of claim 18 wherein said headphone includes a noise cancellation circuit.
